(19) United States
(12) Patent Application Publication
(10) Pub. No.: US 2026/0340802 A1
(43) Pub. Date: Oct. 29, 2026

(54) EQUIPMENT CONDITION DETECTING USING SOUND AND THERMAL IMAGING SYSTEM

(71) Applicant: Saudi Arabian Oil Company, Dhahran (SA)

(72) Inventors: Abdulaziz A. Al-Hudaifah, Dhahran (SA); Sayyed Auwn Muhammad, Dhahran (SA)

(21) Appl. No.: 19/187,308

(22) Filed: Apr. 23, 2025

(51) Int. Cl. G06T 7/00; G06F 3/16

(52) U.S. Cl. CPC G06T 7/0004; G06F 3/16; G06T 2207/10016; G06T 2207/10048; G06T 2207/20084; G06T 2207/30164

(57) ABSTRACT

Systems and methods are disclosed for identifying and predicting faults in rotating equipment. A thermal image and corresponding acoustic signal, captured during the same time interval, are input into a trained data fusion model. The data fusion model generates a fused feature vector from the thermal image and reconstructs the acoustic signal from the fused feature vector. A reconstruction error is calculated as the difference between the actual and reconstructed acoustic signals. The fused feature vector is analyzed using a clustering machine learning model to determine the fault type by assigning fuse feature vector to a cluster, wherein each cluster represents a respective fault type. An anomaly detection model detects anomalies based on the reconstruction error. A predictive model determines whether a potential fault is likely to occur, using current and historical reconstruction error data. If an anomaly or potential fault is detected, the system initiates a corresponding mitigating action.

### TECHNICAL FIELD

This disclosure generally relates to a system and method for detecting and predicting equipment failure using sound and thermal imaging.

### BACKGROUND

Rotating equipment, including pumps, compressors, and turbines, plays a crucial role in various industrial processes. These machines are integral to maintaining continuous operations in sectors such as oil and gas, manufacturing, and power generation. However, the reliability of rotating equipment is often compromised by mechanical wear, aging, and environmental factors, leading to unexpected failures that can cause costly downtime and significant safety risks. Detecting and predicting system failures early is essential to ensure operational continuity, reduce maintenance costs, and enhance safety by allowing timely corrective actions before catastrophic breakdowns occur.

### SUMMARY

This disclosure describes systems and methods for detecting and predicting equipment failure using sound and thermal imaging. The system includes one or more thermal cameras and one or more acoustic sensors mounted to a rotating equipment. The system further includes a computing device (e.g., computer or server) configured to analyze thermal images and acoustic signals captured by the thermal cameras and acoustic sensors to classify detected equipment failure, detect anomalies that indicate equipment failure, and predict potential equipment failures. The system performs one or more mitigating actions in response to detecting an anomaly or predicting a potential equipment failure.

Implementations of the systems and methods of this disclosure can provide various technical benefits. For example, the system enables early detection of potential failures in rotating equipment by combining thermal and acoustic data. Unlike systems that rely on a single data modality, detect faults after they occur and offer limited predictive capabilities, this approach allows for real-time identification of anomalous equipment operation. The system enhances equipment reliability, minimizes unplanned downtime, and supports real-time condition monitoring that is scalable across different equipment types and operational environments.

Additionally, the system employs a convolutional encoder-decoder (CED) architecture to efficiently learn a mapping from thermal image data to corresponding acoustic signal data. This process generates fused feature vectors that are structured for effective utilization in downstream machine learning models for fault classification, anomaly detection, and fault prediction.

The details of one or more implementations of these systems and methods are set forth in the accompanying drawings and the description below. Other features, objects, and advantages of these systems and methods will be apparent from the description and drawings, and from the claims.

### DESCRIPTION OF DRAWINGS

FIG. 1 is a diagram that illustrates an example system for identifying and predicting system failures.

FIG. 2 is a flow diagram that illustrates an example workflow for detecting and predicting equipment faults by combining thermal and acoustic data.

FIG. 3A is a diagram that illustrates an example training process of the data fusion model.

FIG. 3B is a diagram that illustrates an example workflow to classify an equipment fault by clustering fused feature vectors.

FIG. 3C is a diagram illustrating an example workflow for performing anomaly detection and equipment fault prediction.

FIG. 4 is a flowchart for an example method for classifying, detecting, and predicting an equipment fault using the system of FIG. 1.

FIG. 5 is a block diagram illustrating an example computer system used to provide computational functionalities associated with described algorithms, methods, functions, processes, flows, and procedures according to some implementations of the present disclosure.

Like reference symbols in the various drawings indicate like elements.

### DETAILED DESCRIPTION

This specification describes systems and methods for detecting and predicting equipment failure based on sound and thermal imaging. The system includes one or more thermal cameras and one or more acoustic sensors mounted to a rotating equipment. The system further includes a computing device (e.g., computer or server) configured to analyze thermal images and acoustic signals captured by the thermal cameras and acoustic sensors to classify detected equipment failure, detect anomalies that indicate equipment failure, and predict potential equipment failures. The system performs one or more mitigating actions in response to detecting an anomaly or predicting a potential equipment failure. The system can be implemented at various scales, including individual equipment units, equipment trains, plant-wide deployments, or across an entire enterprise.

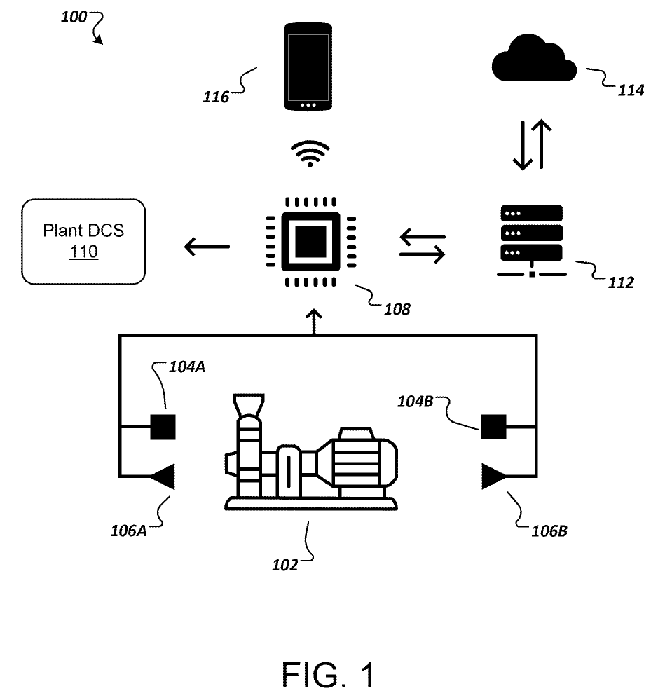

FIG. 1 is a diagram that illustrates an example system 100 for identifying and predicting system failures associated with a field rotating equipment 102 (e.g., a pump, a compressor, a turbine, a gear box, a motor, a blower, or a fan). The system 100 includes thermal cameras 104A, 104B, acoustic sensors 106A, 106B, a field edge device 108, a plant Distributed Control System (DCS) 110, a plant server 112, a corporate cloud server 114, and a plant handheld Personal Digital Assistant (PDA) 116.

The thermal cameras 104A, 104B and acoustic sensors 106A, 106B are mounted to the field rotating equipment 102. The thermal cameras 104 and acoustic sensors 106 are communicatively coupled to the field edge device 108. The thermal cameras and the acoustic sensors respectively capture thermal images and acoustic signals of the field rotating equipment 102. The captured sensor data (e.g., the thermal images and acoustic signals) are transmitted to the field edge device 108. In some embodiments, the sensors 104, 106 are communicatively coupled to the plant server 112, and the sensor data is transmitted to the plant server 112 for processing and analysis. The field edge device 108 can be located near to the plant location or remote from the plant location. While FIG. 1 illustrates two thermal cameras 104 and two acoustic sensors 106, other numbers of thermal cameras and acoustic sensors can be integrated in the system 100.

The field edge device 108 is communicatively coupled to the plant DCS 110, the plant server 112, and the plant handheld PDA 116. In some embodiments, the field edge device 108 implements a plurality of Artificial Intelligence/Machine Learning (AI/ML) models that perform anomaly detection, classification, and fault prediction. The field edge device 108 processes and analyzes the captured sensor data from the thermal cameras 104 and acoustic sensors 106 to generate results including a fault classification, indications of potential equipment failure, and detected anomalies, if present.

The field edge device transmits the results to the plant server 112 for storage and to the plant DCS 110 for display to plant operators. In response to detecting an anomaly or a potential equipment failure, the field edge device 108 may transmit an instruction to the plant handheld PDA 116 to display an alert to notify the plant operator.

The plant DCS 110 is configured to collect and display operational data from the field rotating equipment 102 to operators and to provide operators with control over the equipment’s operation. The plant DCS 110 also receives results from the field edge device 108, such as fault classifications or anomaly alerts, and displays this information to plant operators.

The plant server 112 is communicatively coupled to the corporate cloud server 114. In some embodiments, the plant server 112 implement the AI/ML models to perform anomaly detection, fault classification, and fault prediction. This analysis can be performed by the plant server 112 instead of the field edge device 108. The plant server 112 transmits the results generated by the AI/ML models to the field edge device 108, which in turn transmits the results to the plant DCS 110 for display to plant operators. The field edge device 108 processes the received results to determine whether a fault alert should be generated, and, if so, transmits an instruction to the plant handheld PDA 116 to display an alert notifying the plant operator. The plant server 112 stores the results and transmits the results to the corporate cloud server 114.

The corporate cloud server 114 presents data related to the performance of the rotating equipment 102, including any detected anomalies. The corporate cloud server 114 enables visualization of the rotating equipment operational data through dashboards, allowing users to monitor equipment health, identify potential faults, and assess long-term operational trends. The corporate cloud server 114 which may be implemented as a cluster of servers. The components of the system 100 may be communicatively coupled via wired (e.g., ethernet, serial communication link, USB) or wireless connections (e.g., Wi-Fi, Bluetooth, cellular).

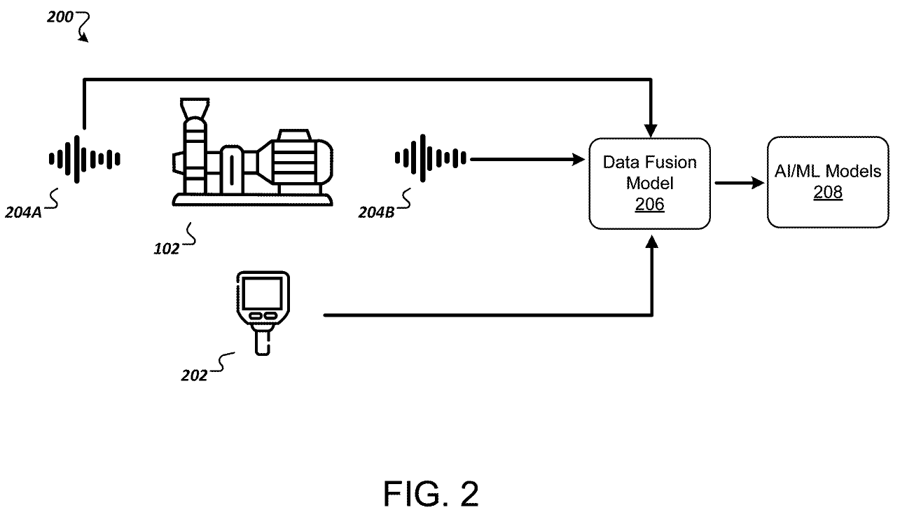

FIG. 2 is a flow diagram that illustrates an example workflow 200 for detecting and predicting equipment faults by combining thermal and acoustic data. The workflow 200 can be implemented by system 100.

The thermal camera 202 captures thermal images of the rotating equipment 102. The thermal camera may capture the thermal images at predefined intervals. In other embodiments, the thermal camera can be configured to capture thermal images when changes are detected, using event-based triggering or motion detection methods. The acoustic sensors 204A, 204B capture acoustic signals generated by the rotating equipment 102. The captured sensor data (e.g., thermal images and acoustic signals) is transmitted to the plant server.

The plant server provides the captured sensor data to a data fusion model 206 and a plurality of AI/ML models 208 to detect and predict equipment faults. For example, the captured sensor data may be provided as pairs, with each pair comprising a thermal image representing a temperature profile at a given timestamp, and a corresponding acoustic signal recorded over a time window that includes the timestamp. The data fusion model 206 is configured to receive and analyze the captured sensor data to generate fused feature vectors, which serve as a representation of the thermal and acoustic state of the equipment. For example, the data fusion model 206 uses thermal images as predictors of acoustic signals by mapping key thermal features to corresponding acoustic signal features.

The plurality of AI/ML models 208 are configured to receive and analyze the fused feature vectors to perform fault classification, identification, and prediction. The AI/ML model 208 may implement clustering ML model to identify the type of fault, anomaly detection ML model to detect the fault, and a predictive ML model to predict potential faults.

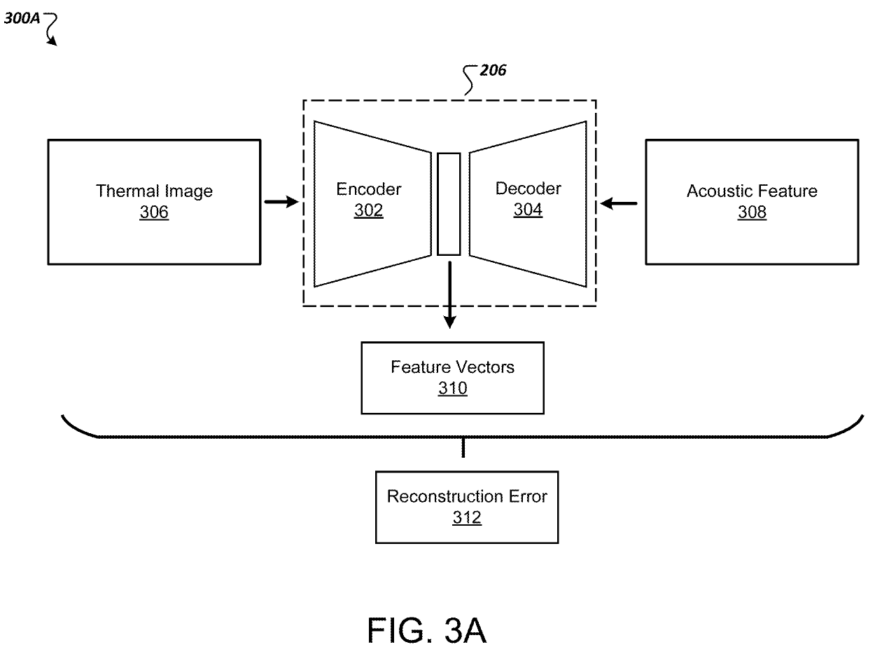

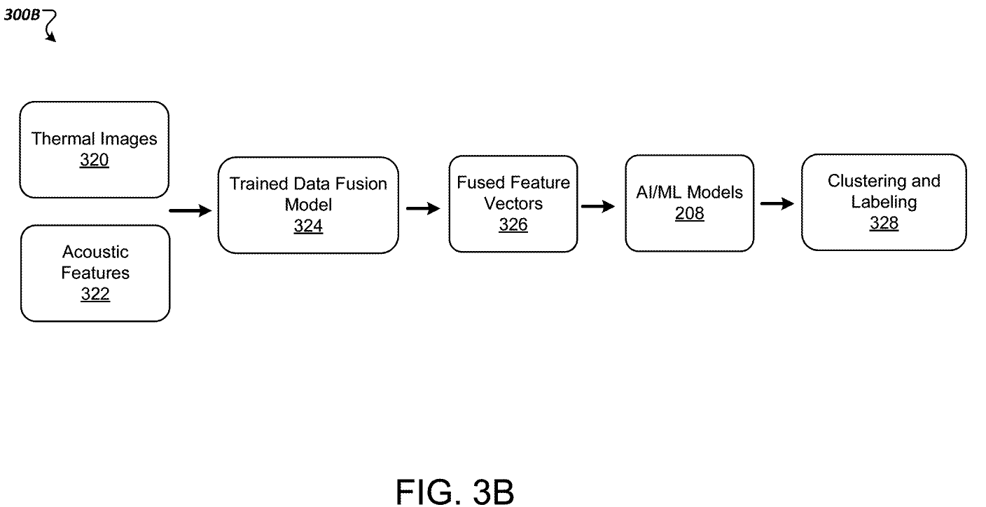

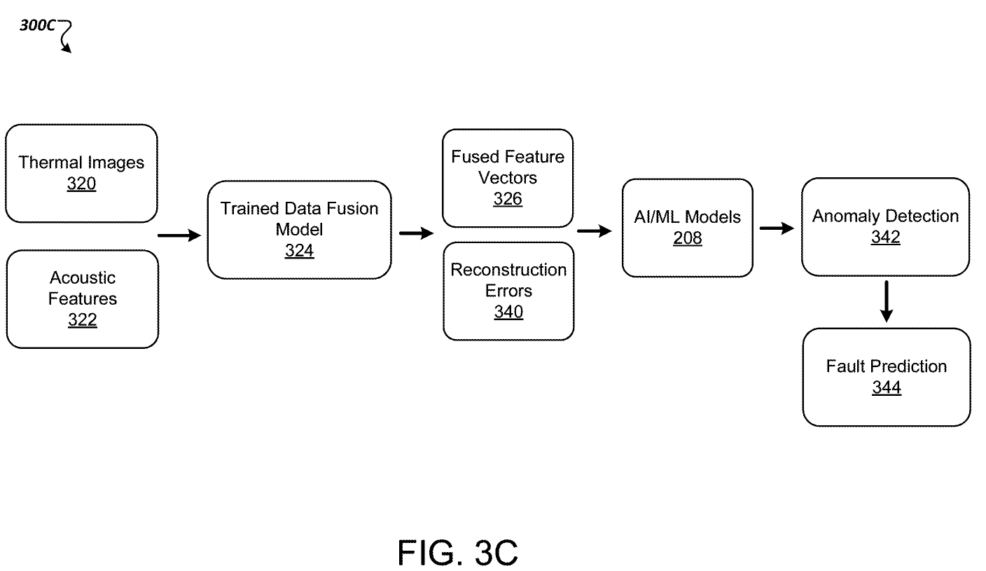

FIG. 3A is a diagram illustrating an example training process 300A of the data fusion model. The data fusion model 206 has a convolutional encoder-decoder (CED) model architecture, which includes an encoder 302 and a decoder 304. In some embodiments, the plant server pre-processes each captured acoustic signal by applying one or more mathematical transformations to the acoustic signal to generate an acoustic feature, which is a representation of key characteristics extracted from the acoustic signal. These characteristics may include frequencies, amplitudes, or temporal patterns. The transformations applied include, but are not limited to, Fourier transform, Mel-Frequency Cepstral Coefficients (MFCCs), Wavelet Transform, Short-Time Fourier Transform (STFT), and Spectrogram Analysis.

The plant server trains the data fusion model 206 in an unsupervised manner to learn a mapping between the thermal images and corresponding acoustic signals. The plant server trains the data fusion model 206 using a training dataset that includes pairs of sensor data, each pair including a thermal image 306 and a corresponding acoustic feature 308 associated to a respective time. The sensor data in the training dataset may be historical data collected from rotating equipment in a healthy operational state. For each pair of sensor data, the encoder 302 of the data fusion model 206 receives a thermal image 306 and compresses it into a low-dimensional fused feature vector 310. The encoder 302 processes the thermal image 306 using a series of convolutional layers to extract pixel-level features, followed by batch normalization to stabilize activations, ReLU for non-linear transformation, and pooling operations to reduce spatial dimensionality. This process generates a compact representation of the thermal image 306, which is the fused feature vector 310.

The decoder 304 of the data fusion model 206 receives the fused feature vector 310 and reconstructs the corresponding acoustic signal. The decoder 304 processes the fused feature vector 310 using a series of upsampling layers to increase spatial resolution, convolutional layers to refine the reconstructed features, and a softmax layer to generate a normalized or probabilistic output. In some embodiments, the softnax layer is omitted to generate a reconstructed acoustic feature (e.g., frequency spectrum of the acoustic signal) or reconstructed acoustic signal.

The data fusion model 206 is trained using a loss function that incorporates a reconstruction error value 312. The reconstruction error value 312 may be calculated as a difference between the reconstructed acoustic feature and the acoustic feature corresponding to the captured acoustic signal. The reconstruction error value 312 serves as an objective function to be minimized during training, guiding updates to the model parameters with each iteration of the training process. This enables the data fusion model 206 to accurately learn a mapping function between thermal images and their corresponding acoustic features, generating fused feature vectors that capture the relationship between the thermal images and acoustic signals.

The plant server may terminate training of the data fusion model 206 when one or more stopping criteria are met. The stopping criteria may include the reconstruction error value falling below a defined threshold, the difference in reconstruction error value between successive iterations falling below a defined threshold, or the completion of a predetermined number of training iterations. The thresholds may be predefined by a user.

FIG. 3B is a diagram that illustrates an example workflow to classify an equipment fault by clustering fused feature vectors. During the testing phase, real-time sensor data of the rotational equipment to be assessed is provided to the AI/ML models to perform fault clustering and labeling 328.

The real-time sensor data, including a plurality of thermal images 320 and corresponding acoustic features 322, is provided to a trained data fusion model 324. The thermal images 320 and the corresponding acoustic features 322 are sequential data samples collected from a rotating equipment at predefined intervals over a period of time. The encoder of the trained data fusion model 324 processes the plurality of thermal images 320 to generate a plurality of fused feature vectors 326. The plant server provides the plurality of fused feature vectors 326 to the AI/ML models 208. The AI/ML models 208 are configured to identify, detect, and predict equipment faults. In some embodiments, the AI/ML models 208 includes a clustering model to identify the type of fault exhibited by a rotating equipment.

The AI/ML model 208 processes the fused feature vectors using a clustering model to form clusters. The clustering model may implement techniques such as K-means clustering, hierarchical clustering, or any distance-based clustering method to group the fused feature vectors based on a similarity metric. Examples of similarity metrics include Euclidean distance, cosine similarity, and Manhattan distance. The similarity metric quantifies how closely related two fused feature vectors are in a multi-dimensional feature space. Each cluster is formed from data points, where each data point represents a fused feature vector corresponding to a rotating equipment. The cluster indicates the operational state of the rotating equipment, such as normal operation, mechanical fault, electrical fault, or critical fault.

The clustering model can be trained using a training dataset including fused feature vectors generated by the trained data fusion model 324 in a supervised or unsupervised manner. In a supervised setting, the fused feature vectors obtained from non-faulty equipment are labelled as “normal”, while fused feature vectors obtained from faulty equipment are labeled according to the specific fault type, such as “mechanical fault”, “electrical fault”, or “critical fault”. Training the clustering model on the labeled data enables the clustering model to learn associations between fused feature vectors and the fault types. During training, the clustering model groups similar fused feature vectors into clusters, with each cluster representing a type of fault. The clusters are labeled based on the known fault types associated with the training data. Once trained, the clustering model groups the fused feature vectors into clusters with most similar features, and the predicted fault type is determined based on the label of the assigned cluster.

FIG. 3C is a diagram illustrating an example workflow 300C for performing anomaly detection and equipment fault prediction. As described above in FIG. 3B, in addition to classifying equipment faults, the AI/ML models 208 are also configured to detect and predict equipment faults.

The real-time sensor data obtained of the rotating equipment to be assessed, including a plurality of thermal images 320 and a plurality of corresponding acoustic features 322, is provided to a trained data fusion model 324. The trained data fusion model 324 processes the plurality of thermal images 320 to generate a plurality of fused feature vectors. In addition to generating a plurality of fused feature vectors 326, the trained data fusion model 324 generates a reconstruction error 340 for each pair of thermal image and corresponding acoustic feature. The decoder of the trained data fusion model 324 processes the fused feature vectors 326 and reconstructs the corresponding acoustic features. The trained data fusion model 324 calculates a reconstruction error for each pair of thermal image and acoustic feature by calculating a difference between the reconstructed acoustic feature and the acoustic feature corresponding to the captured acoustic signal.

The plant server provides the fused feature vectors 326 and the reconstruction errors 340 to the AI/ML models 208. In some embodiments, the AI/ML models 208 further includes an anomaly detection model and a predictive model.

The trained anomaly detection model analyzes the fused feature vectors to perform anomaly detection 342, identifying rotating equipment exhibiting behavior that deviates from normal operating conditions, which may be indicative of an equipment fault. The anomaly detection model may employ a technique such as One Class Support Vector Machine (OCSVM) or any other appropriate anomaly detection technique. The anomaly detection model is trained on a dataset comprising fused feature vectors generated by the data fusion model, obtained from sensor data collected of a rotating equipment operating under normal conditions. The anomaly detection model learns a representation of the normal operating feature space, such as by estimating a decision boundary, density profile, or statistical model based on the training data. The trained anomaly detection model identifies fused feature vectors that deviate from this learned representation as anomalies. The anomaly detection model may utilize various techniques to detect anomalies, including statistical, distance-based, density-based, or probabilistic approaches.

In some embodiments, the trained anomaly detection model detects an equipment fault based on a change in the reconstruction error 340. As the data fusion model is trained on sensor data collected from rotating equipment operating under normal conditions, the trained data fusion model 324 will generate a moderate to high reconstruction error if it processes a fused feature vector that was generated from sensor data obtained from a rotating equipment in a faulty operational state. The reconstruction error generated by the trained data fusion model indicates that the model is unable to accurately reconstruct the acoustic signal corresponding to the thermal image using the mapping learned from normal thermal images and acoustic signal. A change in reconstruction error reflects a change in thermal or acoustic profile of the rotating equipment. The thermal and acoustic profile refers to the sequence of thermal images and corresponding acoustic signals collected over time from the equipment under observation.

For example, a negligible reconstruction error indicates that there was no significant change to the thermal and acoustic profiles, and the anomaly detection model determines that the rotating equipment is operating normally. In another example, a large reconstruction error indicates significant changes in both thermal and acoustic profiles of the rotating equipment, and the anomaly detection model determines that the rotating equipment is experiencing a critical fault. Additionally, a moderate reconstruction error may indicate that there was either change in the thermal profile which indicates an electrical fault, or a change in the acoustic profile which indicates a mechanical fault. The anomaly detection model determines the severity of the equipment fault based on the magnitude of the reconstruction error. In some embodiments, a user may predefine reconstruction error magnitude threshold values that determine the level of the fault severity, such as no fault, minor, moderate, and critical.

Additionally, the trained predictive model performs fault prediction 344 using the reconstruction error values 340. The plant server records reconstruction error values at defined time intervals (e.g., hourly, daily, or weekly) over a duration of time. The reconstruction error values are provided as input to the predictive model, which is trained to predict one or more future reconstruction error values based on historical patterns. The predictive model may be implemented as a regression model, a time-series forecasting model, a recurrent neural network (RNN), or any appropriate machine learning or statistical model.

The predictive model may be trained using sequences of historical reconstruction error values and learns to minimize the difference between predicted future error values and the actual observed errors. The trained predictive model receives the reconstruction error values 340 and generates predicted reconstruction error values. An increasing trend in the predicted reconstruction error indicates a high likelihood of an upcoming fault in the rotating equipment. This enables the system to identify potential equipment failures in advance and perform mitigating actions to prevent or minimize the impact of the equipment failure. In some embodiments, the predictive model compares the trend exhibited by the predicted reconstruction error values to predefined thresholds to determine a severity of the potential fault.

The plant server retrains the AI/ML models on fused feature vectors generated by the data fusion model using sensor data of a rotating equipment. In some embodiments, retraining is performed based on a predefined schedule. In some embodiments, retraining is triggered automatically based on factors such as model performance, model accuracy, fault discovery rate and inspection (e.g., manual intervention with equipment). Retraining may also be manually initiated by a user when necessary.

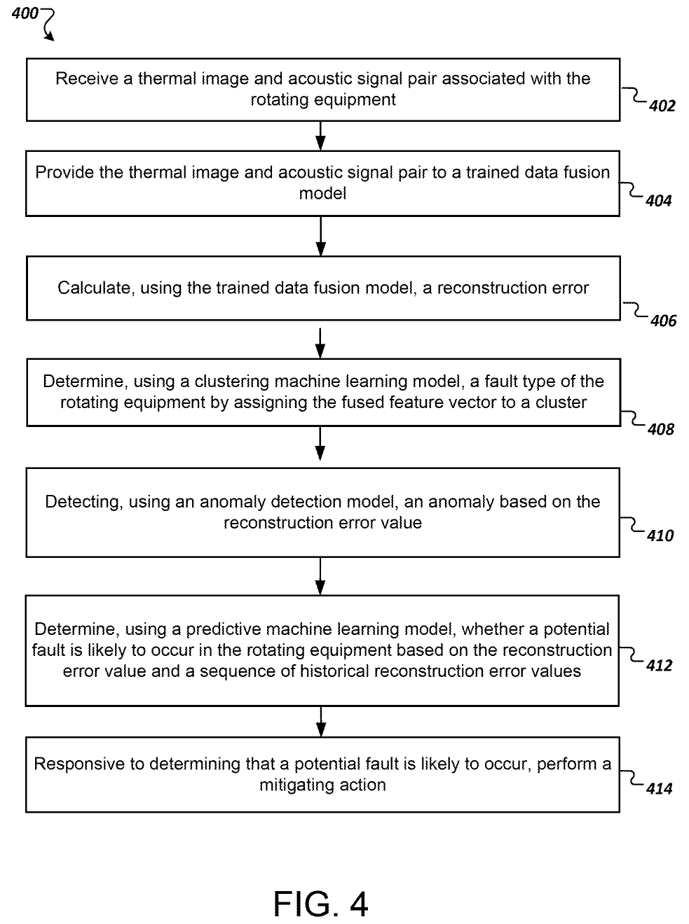

FIG. 4 is a flowchart for an example method for classifying, identifying, and predicting an equipment fault using the system of FIG. 1.

The plant server receives 402 a thermal image and acoustic signal pair associated with the rotating equipment. As described in FIG. 2, the thermal image is captured by a thermal camera while the acoustic signal is captured by an acoustic sensor. The thermal image and acoustic signal pair corresponds to a respective time duration, where the thermal image is captured at a particular timestamp, and the acoustic signal is recorded over a time window that includes the timestamp.

The plant server provides 404 the thermal image and acoustic signal pair to a trained data fusion model. As described in FIG. 3A, the data fusion model has a convolutional encoder-decoder architecture. The data fusion model receives and processes the captured sensor data to generate fused feature vectors that represent a combined thermal-acoustic state of the rotating equipment. The data fusion model is trained to learn a mapping between thermal images and corresponding acoustic signals using sensor data collected from the rotating equipment operating under normal conditions.

The trained data fusion model calculates 406 a reconstruction error. As described in FIG. 3B, the encoder of the trained data fusion model processes the thermal image to generate a fused feature vector. The decoder of the trained data fusion model processes the fused feature vector to generate a reconstructed acoustic signal. The trained data fusion model calculates a reconstruction error value as a difference between the acoustic signal and the reconstructed acoustic signal. The plant server provides the fused feature vector to a clustering machine learning model.

The clustering machine learning model determines 408 a fault type of the rotating equipment by assigning the fused feature vector to a cluster. As described in FIG. 3B, the clustering model is used to identify the type of fault exhibited by a rotating equipment. The clustering model processes the fused feature vector and groups it into a cluster based on a similarity metric. Each cluster indicates the operational state of the rotating equipment, such as normal operation, mechanical fault, electrical fault, or critical fault.

The anomaly detection model detects 410 an anomaly based on the reconstruction error value. As described in FIG. 3C, the plant server provides the fused feature vectors and the corresponding reconstruction error values to the anomaly detection model to perform anomaly detection, identifying rotating equipment exhibiting behavior that deviates from normal operating conditions, which may be indicative of an equipment fault. In some embodiments, the anomaly detection model employs a One Class Support Vector Machine (OCSVM). The anomaly detection model learns a representation of the normal operating feature space through training using a dataset comprising fused feature vectors generated by the data fusion model, obtained from sensor data collected of a rotating equipment operating under normal conditions. The trained anomaly detection model may utilize various techniques to detect anomalies, including statistical, distance-based, density-based, or probabilistic approaches, to identify fused feature vectors that deviate from the learned representation of the normal operating feature space.

In some embodiments, the trained anomaly detection model detects an equipment fault based on a change in the reconstruction error. When the trained data fusion model processes a fused feature vector generated from sensor data corresponding to a faulty operational state of the rotating equipment, it produces a moderate to high reconstruction error. The anomaly detection model evaluates the magnitude of the reconstruction error to determine the severity of the fault. In some embodiments, predefined reconstruction error thresholds may be used to classify fault severity levels, such as no fault, minor, moderate, or critical.

Upon detecting an equipment fault, the system may perform one or more mitigating actions based on the determined fault severity level. The mitigating actions may include generating real-time alerts, generating a pop-up message on a display interface, transmitting signals to the plant handheld PDA to display an alert, and adjusting rotating equipment operations. For example, if the fault was assigned a critical severity level, the mitigating actions taken may include activating an auxiliary motor or activating an auxiliary compressor in addition to generating alerts to notify the relevant plant operators.

The predictive machine learning model determines whether a potential fault is likely to occur in the rotating equipment based on the reconstruction error value and a sequence of historical reconstruction error values. As described in FIG. 3C, the plant server records reconstruction error values at defined time intervals (e.g., hourly, daily, or weekly) over a duration of time. The reconstruction error values are provided as input to the predictive model, which is trained to predict one or more future reconstruction error values based on historical patterns. The trained predictive model receives the reconstruction error values 340 and generates predicted reconstruction error values. In some embodiments, the predictive model compares the trend exhibited by the predicted reconstruction error values to predefined thresholds to determine a severity level of the potential fault. For example, the severity levels may include no fault, minor, moderate, or critical.

Responsive to determining that a potential fault is likely to occur, the system performs a mitigating action. The system may generate real-time alerts, generate a pop-up message on a display interface, transmit signals to the plant handheld PDA to display an alert, and adjust rotating equipment operations. For example, if the fault is classified as critical, the mitigating actions taken may include generating commands to activate an auxiliary motor or activate an auxiliary compressor in addition to generating alerts to notify the relevant plant operators. The system stores data related to rotating equipment performance, detected faults, and potential faults, and uploads the data to a corporate cloud server, which may be implemented as a cluster of servers. The data is presented on dashboards for corporate monitoring and analysis.

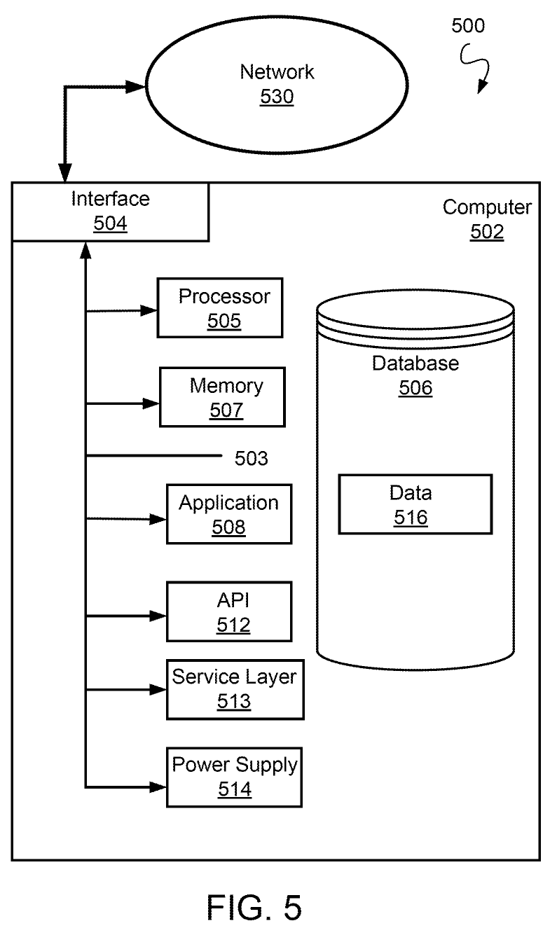

FIG. 5 is a block diagram of an example computer system 500 used to provide computational functionalities associated with described algorithms, methods, functions, processes, flows, and procedures described in the present disclosure, according to some implementations of the present disclosure. The illustrated computer 502 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 502 can include input devices such as keypads, keyboards, and touch screens that can accept user information. Also, the computer 502 can include output devices that can convey information associated with the operation of the computer 502. The information can include digital data, visual data, audio information, or a combination of information. The information can be presented in a graphical user interface (UI) (or GUI).

The computer 502 can serve in a role as a client, a network component, a server, a database, a persistency, or components of a computer system for performing the subject matter described in the present disclosure. The illustrated computer 502 is communicably coupled with a network 530. In some implementations, one or more components of the computer 502 can be configured to operate within different environments, including cloud-computing-based environments, local environments, global environments, and combinations of environments.

At a high level, the computer 502 is an electronic computing device operable to receive, transmit, process, store, and manage data and information associated with the described subject matter. According to some implementations, the computer 502 can also include, or be communicably coupled with, an application server, an email server, a web server, a caching server, a streaming data server, or a combination of servers.

The computer 502 can receive requests over network 530 from a client application (for example, executing on another computer 502). The computer 502 can respond to the received requests by processing the received requests using software applications. Requests can also be sent to the computer 502 from internal users (for example, from a command console), external (or third) parties, automated applications, entities, individuals, systems, and computers.

Each of the components of the computer 502 can communicate using a system bus 503. In some implementations, any, or all of the components of the computer 502, including hardware or software components, can interface with each other or the interface 504 (or a combination of both), over the system bus 503. Interfaces can use an application programming interface (API) 512, a service layer 513, or a combination of the API 512 and service layer 513. The API 512 can include specifications for routines, data structures, and object classes. The API 512 can be either computer-language independent or dependent. The API 512 can refer to a complete interface, a single function, or a set of APIs.

The service layer 513 can provide software services to the computer 502 and other components (whether illustrated or not) that are communicably coupled to the computer 502. The functionality of the computer 502 can be accessible for all service consumers using this service layer. Software services, such as those provided by the service layer 513, can provide reusable, defined functionalities through a defined interface. For example, the interface can be software written in JAVA, C++, or a language providing data in extensible markup language (XML) format. While illustrated as an integrated component of the computer 502, in alternative implementations, the API 512 or the service layer 513 can be stand-alone components in relation to other components of the computer 502 and other components communicably coupled to the computer 502. Moreover, any or all parts of the API 512 or the service layer 513 can be implemented as child or sub-modules of another software module, enterprise application, or hardware module without departing from the scope of the present disclosure.

The computer 502 includes an interface 504. Although illustrated as a single interface 504 in FIG. 5, two or more interfaces 504 can be used according to particular needs, desires, or particular implementations of the computer 502 and the described functionality. The interface 504 can be used by the computer 502 for communicating with other systems that are connected to the network 530 (whether illustrated or not) in a distributed environment. Generally, the interface 504 can include, or be implemented using, logic encoded in software or hardware (or a combination of software and hardware) operable to communicate with the network 530. More specifically, the interface 504 can include software supporting one or more communication protocols associated with communications. As such, the network 530 or the interface's hardware can be operable to communicate physical signals within and outside of the illustrated computer 502.

The computer 502 includes a processor 505. Although illustrated as a single processor 505 in FIG. 5, two or more processors 505 can be used according to particular needs, desires, or particular implementations of the computer 502 and the described functionality. Generally, the processor 505 can execute instructions and can manipulate data to perform the operations of the computer 502, including operations using algorithms, methods, functions, processes, flows, and procedures as described in the present disclosure.

The computer 502 also includes a database 506 that can hold data for the computer 502 and other components connected to the network 530 (whether illustrated or not). For example, database 506 can hold data 516. For example, database 506 can be an in-memory, conventional, or a database storing data consistent with the present disclosure. In some implementations, database 506 can be a combination of two or more different database types (for example, hybrid in-memory and conventional databases) according to particular needs, desires, or particular implementations of the computer 502 and the described functionality. Although illustrated as a single database 506 in FIG. 5, two or more databases (of the same, different, or combination of types) can be used according to particular needs, desires, or particular implementations of the computer 502 and the described functionality. While database 506 is illustrated as an internal component of the computer 502, in alternative implementations, database 506 can be external to the computer 502.

The computer 502 also includes a memory 507 that can hold data for the computer 502 or a combination of components connected to the network 530 (whether illustrated or not). Memory 507 can store any data consistent with the present disclosure. In some implementations, memory 507 can be a combination of two or more different types of memory (for example, a combination of semiconductor and magnetic storage) according to particular needs, desires, or particular implementations of the computer 502 and the described functionality. Although illustrated as a single memory 507 in FIG. 5, two or more memories 507 (of the same, different, or combination of types) can be used according to particular needs, desires, or particular implementations of the computer 502 and the described functionality. While memory 507 is illustrated as an internal component of the computer 502, in alternative implementations, memory 507 can be external to the computer 502.

The application 508 can be an algorithmic software engine providing functionality according to particular needs, desires, or particular implementations of the computer 502 and the described functionality. For example, application 508 can serve as one or more components, modules, or applications. Further, although illustrated as a single application 508, the application 508 can be implemented as multiple applications 508 on the computer 502. In addition, although illustrated as internal to the computer 502, in alternative implementations, the application 508 can be external to the computer 502.

The computer 502 can also include a power supply 514. The power supply 514 can include a rechargeable or non-rechargeable battery that can be configured to be either user- or non-user-replaceable. In some implementations, the power supply 514 can include power-conversion and management circuits, including recharging, standby, and power management functionalities. In some implementations, the power-supply 514 can include a power plug to allow the computer 502 to be plugged into a wall socket or a power source to, for example, power the computer 502 or recharge a rechargeable battery.

There can be any number of computers 502 associated with, or external to, a computer system containing computer 502, with each computer 502 communicating over network 530. Further, the terms “client,” “user,” and other appropriate terminology can be used interchangeably, as appropriate, without departing from the scope of the present disclosure. Moreover, the present disclosure contemplates that many users can use one computer 502 and one user can use multiple computers 502.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example LINUX, UNIX, WINDOWS, MAC OS, ANDROID, or IOS.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

A number of implementations of these systems and methods have been described. Nevertheless, it will be understood that various modifications may be made without departing from the spirit and scope of this disclosure. Accordingly, other implementations are within the scope of the following claims.

### Examples

In an example implementation, a method for identifying and predicting faults in a rotating equipment, the method comprising: receiving a thermal image and acoustic signal pair associated with the rotating equipment, the thermal image and acoustic signal pair corresponding to a respective time duration, wherein the thermal image is captured by a thermal camera and the acoustic signal is captured by an acoustic sensor; providing the thermal image and acoustic signal pair to a trained data fusion model; calculating, using the trained data fusion model, a reconstruction error. The calculating comprising generating a fused feature vector from the thermal image using an encoder of the trained data fusion model; generating a reconstructed acoustic signal from the fused feature vector using a decoder of the trained data fusion model; and calculating a reconstruction error value as a difference between the acoustic signal and the reconstructed acoustic signal. The method further comprises determining, using a clustering machine learning model, a fault type of the rotating equipment by assigning the fused feature vector to a cluster, wherein each cluster represents a fault type of the rotating equipment; detecting, using an anomaly detection machine learning model, an anomaly based on the reconstruction error value; determining, using a predictive machine learning model, whether a potential fault is likely to occur in the rotating equipment based on the reconstruction error value and a sequence of historical reconstruction error values; and responsive to determining that a potential fault is likely to occur, performing a mitigating action.

In an aspect combinable with the example implementation, wherein the data fusion model has a convolutional encoder-decoder (CED) model architecture.

In another aspect combinable with any of the previous aspects, further comprising training the data fusion model in an unsupervised manner, using thermal images and acoustic signals captured by the thermal camera and the acoustic sensor from the rotating equipment in a healthy operational state.

In another aspect combinable with any of the previous aspects, wherein training the data fusion model further comprises performing an iterative training loop, each iteration comprising: providing, to the data fusion model, a thermal image and acoustic signal pair corresponding to a respective time duration; generating a feature vector from the thermal image using an encoder; generating a reconstructed acoustic signal from the feature vector using a decoder; and calculating a reconstruction error between the acoustic signal and the reconstructed acoustic signal, wherein the reconstruction error is used to adjust weights of the data fusion model to learn a mapping between the thermal images and the acoustic signals.

In another aspect combinable with any of the previous aspects, wherein the anomaly detection machine learning model comprises a One Class Support Vector Machine (OCSVM).

In another aspect combinable with any of the previous aspects, wherein the anomaly is assigned a severity level based on a magnitude of the reconstruction error.

In another aspect combinable with any of the previous aspects, wherein the mitigating action comprises generating real-time alerts, adjusting rotating equipment operations, activating an auxiliary motor, or activating an auxiliary compressor.

In another example implementation, a system for identifying and predicting faults in a rotating equipment, the system comprising: a thermal camera mounted to the rotating equipment, configured to capture thermal images of the rotating equipment; an acoustic sensor mounted to the rotating equipment, configured to capture acoustic signals from the rotating equipment; and a computing device. The computing device comprising one or more processors; and a memory unit storing instructions that when executed by the one or more processors cause the one or more processors to perform operations comprising: receiving a thermal image and acoustic signal pair associated with the rotating equipment, the thermal image and acoustic signal pair corresponding to a respective time duration, wherein the thermal image is captured by the thermal camera and the acoustic signal is captured by the acoustic sensor; providing the thermal image and acoustic signal pair to a trained data fusion model; calculating, using the trained data fusion model, a reconstruction error. The calculating comprising generating a fused feature vector from the thermal image using an encoder of the trained data fusion model; generating a reconstructed acoustic signal from the fused feature vector using a decoder of the trained data fusion model; and calculating a reconstruction error value as a difference between the acoustic signal and the reconstructed acoustic signal. The operations further comprises determining, using a clustering machine learning model, a fault type of the rotating equipment by assigning the fused feature vector to a cluster, wherein each cluster represents a fault type of the rotating equipment; detecting, using an anomaly detection machine learning model, an anomaly based on the reconstruction error value; determining, using a predictive machine learning model, whether a potential fault is likely to occur in the rotating equipment based on the reconstruction error value and a sequence of historical reconstruction error values; and responsive to determining that a potential fault is likely to occur, performing a mitigating action.

In an aspect combinable with the example implementation, wherein the data fusion model has a convolutional encoder-decoder (CED) model architecture.

In another aspect combinable with any of the previous aspects, further comprising training the data fusion model in an unsupervised manner, using thermal images and acoustic signals captured by the thermal camera and the acoustic sensor from the rotating equipment in a healthy operational state.

In another aspect combinable with any of the previous aspects, wherein training the data fusion model further comprises performing an iterative training loop, each iteration comprising: providing, to the data fusion model, a thermal image and acoustic signal pair corresponding to a respective time duration; generating a feature vector from the thermal image using an encoder; generating a reconstructed acoustic signal from the feature vector using a decoder; and calculating a reconstruction error between the acoustic signal and the reconstructed acoustic signal, wherein the reconstruction error is used to adjust weights of the data fusion model to learn a mapping between the thermal images and the acoustic signals.

In another aspect combinable with any of the previous aspects, wherein the anomaly detection machine learning model comprises a One Class Support Vector Machine (OCSVM).

In another aspect combinable with any of the previous aspects, wherein the anomaly is assigned a severity level based on a magnitude of the reconstruction error.

In another aspect combinable with any of the previous aspects, wherein the mitigating action comprises generating real-time alerts, adjusting rotating equipment operations, activating an auxiliary motor, or activating an auxiliary compressor.

In another example implementation, one or more non-transitory non-transitory computer-readable mediums storing instructions identifying and predicting faults in a rotating equipment, the instructions being executable by one or more processors to cause performance of operations comprising: receiving a thermal image and acoustic signal pair associated with the rotating equipment, the thermal image and acoustic signal pair corresponding to a respective time duration, wherein the thermal image is captured by a thermal camera and the acoustic signal is captured by an acoustic sensor; providing the thermal image and acoustic signal pair to a trained data fusion model; calculating, using the trained data fusion model, a reconstruction error. The calculating comprising generating a fused feature vector from the thermal image using an encoder of the trained data fusion model; generating a reconstructed acoustic signal from the fused feature vector using a decoder of the trained data fusion model; and calculating a reconstruction error value as a difference between the acoustic signal and the reconstructed acoustic signal. The method further comprises determining, using a clustering machine learning model, a fault type of the rotating equipment by assigning the fused feature vector to a cluster, wherein each cluster represents a fault type of the rotating equipment; detecting, using an anomaly detection machine learning model, an anomaly based on the reconstruction error value; determining, using a predictive machine learning model, whether a potential fault is likely to occur in the rotating equipment based on the reconstruction error value and a sequence of historical reconstruction error values; and responsive to determining that a potential fault is likely to occur, performing a mitigating action.

In an aspect combinable with the example implementation, wherein the data fusion model has a convolutional encoder-decoder (CED) model architecture.

In another aspect combinable with any of the previous aspects, further comprising training the data fusion model in an unsupervised manner, using thermal images and acoustic signals captured by the thermal camera and the acoustic sensor from the rotating equipment in a healthy operational state.

In another aspect combinable with any of the previous aspects, wherein training the data fusion model further comprises performing an iterative training loop, each iteration comprising: providing, to the data fusion model, a thermal image and acoustic signal pair corresponding to a respective time duration; generating a feature vector from the thermal image using an encoder; generating a reconstructed acoustic signal from the feature vector using a decoder; and calculating a reconstruction error between the acoustic signal and the reconstructed acoustic signal, wherein the reconstruction error is used to adjust weights of the data fusion model to learn a mapping between the thermal images and the acoustic signals.

In another aspect combinable with any of the previous aspects, wherein the anomaly detection machine learning model comprises a One Class Support Vector Machine (OCSVM).

In another aspect combinable with any of the previous aspects, wherein the anomaly is assigned a severity level based on a magnitude of the reconstruction error.

In another aspect combinable with any of the previous aspects, wherein the mitigating action comprises generating real-time alerts, adjusting rotating equipment operations, activating an auxiliary motor, or activating an auxiliary compressor.

What is claimed is:

1. A method for identifying and predicting faults in a rotating equipment, the method comprising:
receiving a thermal image and acoustic signal pair associated with the rotating equipment, the thermal image and acoustic signal pair corresponding to a respective time duration, wherein the thermal image is captured by a thermal camera and the acoustic signal is captured by an acoustic sensor;
providing the thermal image and acoustic signal pair to a trained data fusion model;
calculating, using the trained data fusion model, a reconstruction error, comprising:
generating a fused feature vector from the thermal image using an encoder of the trained data fusion model;
generating a reconstructed acoustic signal from the fused feature vector using a decoder of the trained data fusion model; and
calculating a reconstruction error value as a difference between the acoustic signal and the reconstructed acoustic signal;
determining, using a clustering machine learning model, a fault type of the rotating equipment by assigning the fused feature vector to a cluster, wherein each cluster represents a fault type of the rotating equipment;
detecting, using an anomaly detection machine learning model, an anomaly based on the reconstruction error value;
determining, using a predictive machine learning model, whether a potential fault is likely to occur in the rotating equipment based on the reconstruction error value and a sequence of historical reconstruction error values; and
responsive to determining that a potential fault is likely to occur, performing a mitigating action.

2. The method of claim 1, wherein the data fusion model has a convolutional encoder-decoder (CED) model architecture.

3. The method of claim 1, further comprising training the data fusion model in an unsupervised manner, using thermal images and acoustic signals captured by the thermal camera and the acoustic sensor from the rotating equipment in a healthy operational state.

4. The method of claim 3, wherein training the data fusion model further comprises performing an iterative training loop, each iteration comprising:
providing, to the data fusion model, a thermal image and acoustic signal pair corresponding to a respective time duration;
generating a fused feature vector from the thermal image using an encoder;
generating a reconstructed acoustic signal from the fused feature vector using a decoder; and
calculating a reconstruction error between the acoustic signal and the reconstructed acoustic signal, wherein the reconstruction error is used to adjust weights of the data fusion model to learn a mapping between the thermal images and the acoustic signals.

5. The method of claim 1, wherein the anomaly detection machine learning model comprises a One Class Support Vector Machine (OCSVM).

6. The method of claim 1, wherein the anomaly is assigned a severity level based on a magnitude of the reconstruction error.

7. The method of claim 1, wherein the mitigating action comprises generating real-time alerts, adjusting rotating equipment operations, activating an auxiliary motor, activating an auxiliary compressor, or any combination thereof.

8. A system for identifying and predicting faults in a rotating equipment, the system comprising:
a thermal camera mounted to the rotating equipment, configured to capture thermal images of the rotating equipment;
an acoustic sensor mounted to the rotating equipment, configured to capture acoustic signals from the rotating equipment; and
a computing device, comprising:
one or more processors; and
a memory unit storing instructions that when executed by the one or more processors cause the one or more processors to perform operations comprising:
receiving a thermal image and acoustic signal pair associated with the rotating equipment, the thermal image and acoustic signal pair corresponding to a respective time duration, wherein the thermal image is captured by the thermal camera and the acoustic signal is captured by the acoustic sensor;
providing the thermal image and acoustic signal pair to a trained data fusion model;
calculating, using the trained data fusion model, a reconstruction error, comprising:
generating a fused feature vector from the thermal image using an encoder of the trained data fusion model;
generating a reconstructed acoustic signal from the fused feature vector using a decoder of the trained data fusion model; and
calculating a reconstruction error value as a difference between the acoustic signal and the reconstructed acoustic signal;
providing the fused feature vector to a trained machine learning model;
determining, using a clustering machine learning model, a fault type of the rotating equipment by assigning the fused feature vector to a cluster, wherein each cluster represents a fault type of the rotating equipment;
detecting, using an anomaly detection machine learning model, an anomaly based on the reconstruction error value;
determining, using a predictive machine learning model, whether a potential fault is likely to occur in the rotating equipment based on the reconstruction error value and a sequence of historical reconstruction error values; and
responsive to determining that a potential fault is likely to occur, performing a mitigating action.

9. The system of claim 8, wherein the data fusion model has a convolutional encoder-decoder (CED) model architecture.

10. The system of claim 8, further comprising training the data fusion model in an unsupervised manner, using thermal images and acoustic signals captured by the thermal camera and the acoustic sensor from the rotating equipment in a healthy operational state.

11. The system of claim 10, wherein training the data fusion model further comprises performing an iterative training loop, each iteration comprising:
providing, to the data fusion model, a thermal image and acoustic signal pair corresponding to a respective time duration;
generating a fused feature vector from the thermal image using an encoder;
generating a reconstructed acoustic signal from the fused feature vector using a decoder; and
calculating a reconstruction error between the acoustic signal and the reconstructed acoustic signal, wherein the reconstruction error is used to adjust weights of the data fusion model to learn a mapping between the thermal images and the acoustic signals.

12. The system of claim 8, wherein the anomaly detection machine learning model comprises a One Class Support Vector Machine (OCSVM).

13. The system of claim 8, wherein the anomaly is assigned a severity level based on a magnitude of the reconstruction error.

14. The system of claim 8, wherein the mitigating action comprises generating real-time alerts, adjusting rotating equipment operations, activating an auxiliary motor, activating an auxiliary compressor, or any combination thereof.

15. One or more non-transitory computer-readable mediums storing instructions identifying and predicting faults in a rotating equipment, the instructions being executable by one or more processors to cause performance of operations comprising:
receiving a thermal image and acoustic signal pair associated with the rotating equipment, the thermal image and acoustic signal pair corresponding to a respective time duration, wherein the thermal image is captured by a thermal camera and the acoustic signal is captured by an acoustic sensor;
providing the thermal image and acoustic signal pair to a trained data fusion model;
calculating, using the trained data fusion model, a reconstruction error, comprising:
generating a fused feature vector from the thermal image using an encoder of the trained data fusion model;
generating a reconstructed acoustic signal from the fused feature vector using a decoder of the trained data fusion model; and
calculating a reconstruction error value as a difference between the acoustic signal and the reconstructed acoustic signal;
determining, using a clustering machine learning model, a fault type of the rotating equipment by assigning the fused feature vector to a cluster, wherein each cluster represents a fault type of the rotating equipment;
detecting, using an anomaly detection machine learning model, an anomaly based on the reconstruction error value;
determining, using a predictive machine learning model, whether a potential fault is likely to occur in the rotating equipment based on the reconstruction error value and a sequence of historical reconstruction error values; and
responsive to determining that a potential fault is likely to occur, performing a mitigating action.

16. The one or more non-transitory computer-readable mediums of claim 15, wherein the data fusion model has a convolutional encoder-decoder (CED) model architecture.

17. The one or more non-transitory computer-readable mediums of claim 15, further comprising training the data fusion model in an unsupervised manner, using thermal images and acoustic signals captured by the thermal camera and the acoustic sensor from the rotating equipment in a healthy operational state.

18. The one or more non-transitory computer-readable mediums of claim 17, wherein training the data fusion model further comprises performing an iterative training loop, each iteration comprising:
providing, to the data fusion model, a thermal image and acoustic signal pair corresponding to a respective time duration;
generating a fused feature vector from the thermal image using an encoder;
generating a reconstructed acoustic signal from the fused feature vector using a decoder; and
calculating a reconstruction error between the acoustic signal and the reconstructed acoustic signal, wherein the reconstruction error is used to adjust weights of the data fusion model to learn a mapping between the thermal images and the acoustic signals.

19. The one or more non-transitory computer-readable mediums of claim 15, wherein the anomaly detection machine learning model comprises a One Class Support Vector Machine (OCSVM).

20. The one or more non-transitory computer-readable mediums of claim 15, wherein the mitigating action comprises generating real-time alerts, adjusting rotating equipment operations, activating an auxiliary motor, activating an auxiliary compressor, or any combination thereof.
